(19) United States
(12) Patent Application Publication
(10) Pub. No.: US 2011/0146760 A1
(43) Pub. Date: Jun. 23, 2011

(54) PHOTOVOLTAIC MODULE

(75) Inventors: Ingram Eusch, Villach (AT); Rudolf Frank, Pischeldorf (AT); Armin Kogler, Treibach (AT)

(73) Assignee: Kioto Photovoltaics GmbH

(21) Appl. No.: 12/880,220

(22) Filed: Sep. 13, 2010

(30) Foreign Application Priority Data
Dec. 17, 2009 (EP) EP 09 015 596.1

(51) Int. Cl. H01L 31/048

(52) U.S. Cl. 136/251

(57) ABSTRACT

The invention concerns a photovoltaic module with a transparent cover, that forms a first main surface of the module, a protective layer, that runs parallel and with a distance to the cover and forms a second main surface of the module, a first adhesive layer between the cover and a photovoltaic layer formed from a multitude of cells, a second adhesive layer between the protective layer and the photovoltaic layer, wherein the first and second adhesive layer are extending into an area between the cells of the photovoltaic layer and around the cells and are projecting the module circumferentially at the edge by 0.1 to 3 mm.

### FIELD OF THE INVENTION

The invention concerns a photovoltaic module.

### BACKGROUND OF THE INVENTION

Main components of such a solar module with solar cells from crystalline silicon are a transparent cover, foils in which the solar cells with their associated electrical contacting and electrical terminal elements are embedded and a protective layer opposing the cover also called back sheet.

It is known to arrange the cover, the foils (adhesive layers) with intermediate photovoltaic cells and the protective layer on top of each other to be combined to a compact cavity free unit, the photovoltaic module, in a vacuum laminating process. Because of the heating during the lamination process (for example 200° C.) said foils turn viscous, fill the cavities between and around the photovoltaic cells and simultaneously form the desired adhesive joint between cover and photovoltaic layer and photovoltaic layer and protective layer respectively.

After the lamination process the parts of the foil and the protective layer protruding laterally (protruding parts of the adhesive layer) are being cut off exactly to the design of the transparent cover. For this purpose a knife is guided along the edge of the cover.

This procedure has various disadvantages:

During the cutting off of protruding parts of the foil/adhesive layer/protective layer the cover can be damaged at its edge. By this damage undesirable wedges are formed between the individual layers of the module in which afterwards moisture can intrude, which is particularly problematic in freeze-/thaw-cycles.

Such wedges may also form in transition regions between the individual layers laterally. The aforesaid problems emerge analogously.

The transparent cover, usually made of glass, is regularly not exactly rectangular. While two opposing side edges are usually parallel this is often not true for the connecting side edges. Often there is a trapezoid geometry or a rhombus basic form.

Both causes problems, when the photovoltaic module is afterwards inserted into the according frame which is exactly rectangular. Usually a reliable sealing cannot be achieved in that case.

One object of the invention it to avoid the aforesaid disadvantages.

### SUMMARY OF THE INVENTION

The basic idea of the invention is the understanding that an essential problem is that irregularities (discontinuities) up to holes or cavities in the edge area of the module are responsible for the problems outlined.

These irregularities can be removed after the lamination process and the cutting by a separate processing step, for example by a subsequent sealing. The additional processing step would not only extend the manufacturing time but also cause additional costs.

The essential idea of the invention is therefore to use the foils (adhesive layers themselves) for sealing the edge of the module.

As disclosed the foils (adhesive foils) melt during the lamination process, turn viscous and then fill for example sections between adjacent photovoltaic cells and/or sections around the photovoltaic cells as well as any other cavities. In this process a part of the material flows inevitably also over the circumference marginal area and then further along the marginal area in particularly of the transparent cover.

In other words: a circumferential coating from the material of the adhesive layer is formed in-situ, that is not only protecting the marginal area of the cover but also covers connection areas to the cover and the protective layer respectively. A virtually monolithic circumferential (along its edge) coating is formed that is starting from a section between protective layer and cover that is running along the edge and is circumferentially projecting beyond the cover.

The subsequent cutting is done in such a way that the adhesive layer is circumferentially projecting the module at its edge only by 0.1 to 3 mm. In other words: contrary to the state of the art the projecting sections of the adhesive layer and/or the protective layer are not being flush-cut to the overall dimensions of the cover, but a projecting edge of adhesive layer(s) and possibly of the protective layer remains.

This projection protects the cover at its edge as well as any terminal areas of the cover and/or protective layer to adjacent parts of the photovoltaic module reliably.

At the same time the cutting can take place in such a way that the finished module has an exactly rectangular form not dependent on said tolerances of the cover.

It is known that the cover can for example exhibit dimensional tolerances from +/−1.5 mm at a basic dimension of 985×1.500 mm with regard to length and width (or +/−3.2 mm diagonally). From this a tolerance factor can be calculated that can be improved by cutting according to the invention by at least 50%, but also by at least 90% that is with regard to tolerances according to the basic dimension of for example +/−0.2 mm (length, width).

The respective cutting is facilitated if the cover shows at least three, for a rectangular cover usually four defined markings that are optically detected before cutting to allow a rectangular cutting to the greatest possible extent.

These markings can be dots, crosses or angles in the corner region of the cover and remain there, that is why they should be designed inconspicuously in their size and color.

According to one embodiment the first adhesive layer extends continuously until projecting corresponding edge sections of the cover. This may apply analogously for the second adhesive layer.

According to one embodiment the circumferential projection at the edge is not more than 1 mm and according to another embodiment at least 0.2 mm.

As already mentioned the adhesive layer may be formed from an adhesive foil for example from cross-linked ethylene-vinyl-acetate (EVA). Such foils or adhesive layers are state of the art for solar modules.

This also applies for the protective layer (back sheet) for a composite foil for example on the basis of polyvinylfluoride (PVF). Such a foil has a relatively high stability and reflectivity. It is at the same time weatherproof and UV-resistant.

Whereas the foils or the adhesive layers formed thereof usually have a thickness, perpendicularly to the cover, of 0.1 to 1.0 mm, and this also applies for the thickness of the protective layer, a material thickness of 0.2 to 0.8 mm for the adhesive foils and from 0.2 to 0.7 mm for the protective foil has proved adequate wherein the photovoltaic cells usually have a thickness of up to 0.2 mm, so that with said foil thicknesses it is ensured that these can also fill cavities between and adjacent to the cells during the lamination process.

Other features of the inventions arise from the features of the sub claims as well as the other application documents.

The invention is described in more detail below with one embodiment. This shows each in a simplified representation.

### BRIEF DESCRIPTION OF THE DRAWINGS

FIG. 1 shows the arrangement of cover, foils and protective layer as well as photovoltaic cells prior to the lamination process.

FIG. 2 shows the arrangement of cover, foils and protective layer as well as photovoltaic cells after the lamination process.

FIG. 3 shows a top view on the module according to FIG. 2 (from below).

In the figures components which are similar or with similar effects are represented with identical characters.

### DETAILED DESCRIPTION OF THE INVENTION

The production of a photovoltaic module is done as follows:

On top of a transparent cover 10, here: made of glass, an EVA-foil 12 is placed, on top of the EVA-foil 12 photovoltaic cells 14 are placed (which are each interconnected to a string) there on top again a second EVA-foil 16 and finally there on top a protective layer 18 made of polyvinylfluoride.

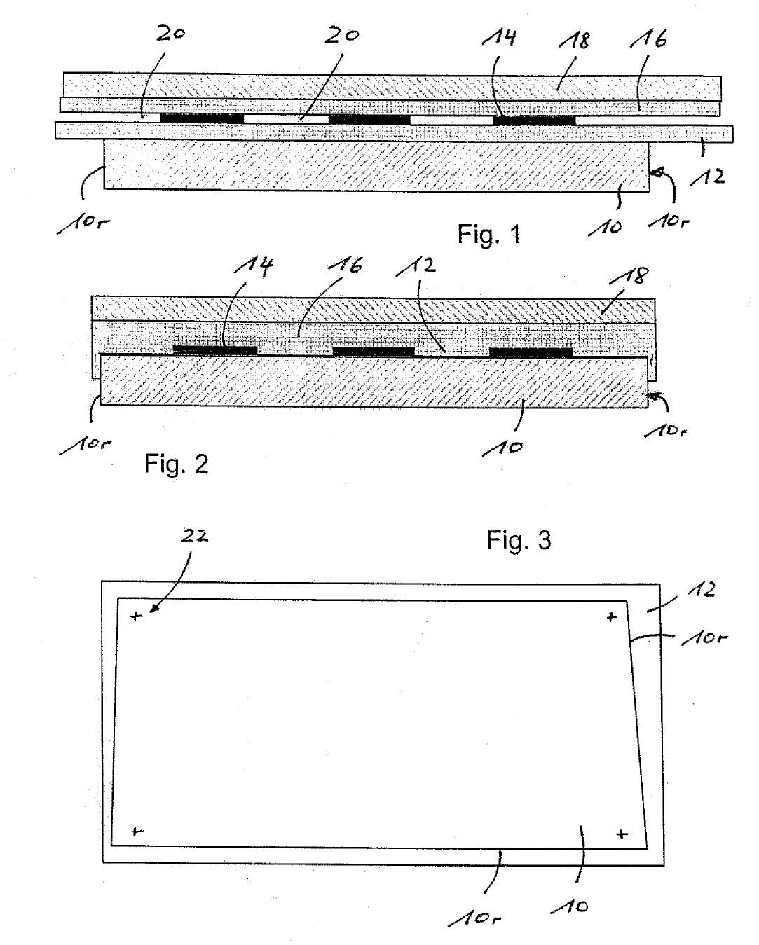

FIG. 1 shows that the foils 12, 16 as well as the protective layer 18 are projecting the cover 10 (on all sides) at its edge. FIG. 1 also shows that between adjacent cells 14 or around the cells 14 respectively sections 20 are present that form cavities.

Within a vacuum lamination line foils 12, 16 turn viscous at approximately 150° C. and flow into the section 20 and over the peripheral region 10r of the cover 10. The foil material cures as soon as the maximum temperature within the lamination line is set back to ambient temperatures.

In a subsequent cutting station the dimensioning of photovoltaic module takes place in such a way that the adhesive layers, that are made up of the foils 12, 16, are slightly projecting the edge 10r of the cover 10, in this case: about 0.2 mm as schematically represented in FIG. 2.

The photovoltaic module shown in a vertical cross section in FIG. 2 has a more or less exact outer rectangular geometry as results from the top view according to FIG. 3, wherein the cover 10 itself has (exaggeratedly shown in FIG. 3) a trapezoidal design which was compensated by cutting off the projections of foils 12, 16 and the protective layer 18 accordingly.

For this purpose the cover 10 made of glass has four cross-shaped labels 22 in the corner region of the cover 10, wherein these labels 22 define the position of the cover 10 in the cutting station so that it can subsequently be cut to size exactly.

From the trapezoidal geometry of the cover 10 it results inevitably that the projection 12u of the adhesive layer 12 (adhesive foil 12) is not equal on all sides. This is not only accepted but explicitly desired, so that the module obtains an overall rectangular form and can then be mounted fitting exactly in an according frame.

Having described the invention, the following is claimed:

1. A photovoltaic module comprising:
a transparent cover that forms a first main surface of the module,
a protective layer that runs parallel and with a distance to the cover and forms a second main surface of the module,
a first adhesive layer between the cover and a photovoltaic layer formed from a multitude of cells,
a second adhesive layer between the protective layer and the photovoltaic layer, wherein
the first and second adhesive layer extend into an area between the cells of the photovoltaic layer and around the cells and are projecting the module circumferentially at its edge by 0.1 to 3 mm.

2. A photovoltaic module according to claim 1, wherein at least the first adhesive layer extends continuously until projecting corresponding edge areas of the cover.

3. A photovoltaic module according to claim 1, wherein the first and the second adhesive layer are circumferentially projecting the module at its edge by not more than 1 mm.

4. A photovoltaic module according to claim 1, wherein the first and the second adhesive layer are circumferentially projecting the module at its edge by not more than 0.2 mm.

5. A photovoltaic module according to claim 1, wherein at least one adhesive layer is formed from an adhesive foil.

6. A photovoltaic module according to claim 5, wherein at least one adhesive foil consists of cross-linked ethylene-vinyl-acetate.

7. A photovoltaic module according to claim 1, wherein at least one adhesive layer has a thickness, perpendicular to the cover, of 0.1 to 1.0 mm.

8. A photovoltaic module according to claim 1, wherein the protective layer has a thickness, perpendicular to the cover, of 0.1 to 1.0 mm.

9. A photovoltaic module according to claim 1, wherein the protective layer is made of a composite foil.

10. A photovoltaic module according to claim 1, wherein the cover is made of glass.

11. A photovoltaic module according to claim 1, wherein the cover has at least three markings at a defined distance to each other.

12. A photovoltaic module according to claim 1, wherein the cover has four markings, which form the corners of a fictitious rectangle.
